(19) United States
(12) Patent Application Publication
(10) Pub. No.: US 2010/0108136 A1
(43) Pub. Date: May 6, 2010

(54) SOLAR CELL

(75) Inventor: YUAN-CHIEH DING, Tucheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/495,782

(22) Filed: Jun. 30, 2009

(30) Foreign Application Priority Data
Oct. 30, 2008 (CN) 200810305285.4

(51) Int. Cl. H01L 31/0216

(52) U.S. Cl. 136/256

(57) ABSTRACT

A solar cell includes a photoelectric conversion module having a light incident surface for receiving light and converting the light into electric energy, and glass layer containing europium therein applied on the light incident surface. The glass layer modulates wavelength of received light to a higher level and transmits modulated light to the light incident surface.

### BACKGROUND

1. Technical Field

The present invention relates generally to a solar cell.

2. Description of Related Art

One of the factors limiting the efficiency of a solar cell is the light conversion rate of photoelectric material (e.g., cadmium telluride based and silicon-based photoelectric material). Generally, these photoelectric materials can merely absorb light which has a wavelength in the range from 400 nanometers (nm) to 1100 nanometers and converts it into electric energy. That is, the light out of this wavelength range is wasted.

Therefore, what is needed is to provide a solar cell which is capable of overcoming the aforementioned problems.

### BRIEF DESCRIPTION OF THE DRAWINGS

Many aspects of the present solar cell can be better understood with references to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic view showing a solar cell having a glass layer in accordance with an embodiment.

FIG. 2 is an ultraviolet visible absorption spectrum of the glass layer in FIG. 1.

FIG. 3 is a fluorescence spectrum at 465 nm excitation of glass layer in FIG. 1

### DETAILED DESCRIPTION

Various embodiments of a solar cell will be described in detail with reference to the accompanying drawings.

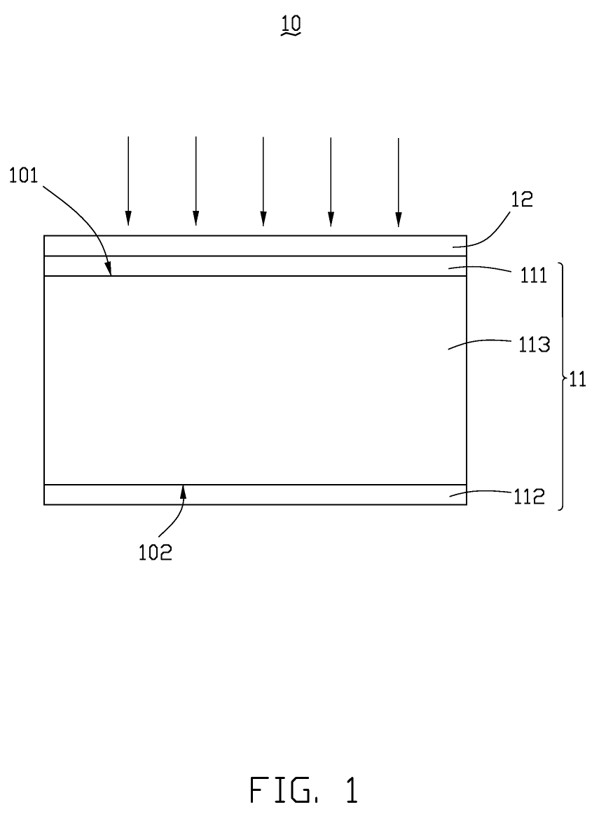

Referring to FIG. 1, a solar cell 10 in accordance with an embodiment includes a photoelectric conversion module 11 provided with a glass layer 12 for modulating wavelength of received light to a higher level and transmitting modulated light to the photoelectric conversion module 11.

The photoelectric conversion module 11 includes a front electrode 111, a back electrode 112, and a photoelectric layer sandwiched between the front electrode 111 and the back electrode 112. The photoelectric layer 113 has a light incident surface 101 and a surface 102 opposite to the light incident surface 101. The front electrode 111 is in contact with the light incident surface 101, and the back electrode 112 is in contact with the surface 102. In the present embodiment, the front electrode 111 is a transparent conductive layer. When a light beams is irradiated on the solar cell; it passes through the transparent conductive layer and enters into the photoelectric layer 113. The photoelectric layer 113 receives the light beam and converts is into electric energy. The front electrode 111 and the back electrode 112 are electronically connected to one or more external loads thereby transmitting electric energy generated in the solar cell 10 to the external loads.

The transparent conductive layer is comprised of a transparent conductive material (e.g., indium tin oxide). In other embodiments, the transparent conductive layer includes a transparent substrate (e.g., a glass substrate) and a transparent film deposited on the transparent substrate. Examples of the transparent film include films of cadmium oxide (CdO), zinc oxide (ZnO), binary oxides of zinc which have a formula of ZnO:M, wherein M represents aluminum (Al), gallium (Ga), indium (In), and fluorine (F). The back electrode 112 is comprised of a metal (e.g., aluminum, and copper). The photoelectric layer 113 is comprised of a material selected from the group consisting of silicon-based semiconductors, group III-V semiconductors, and group II-VI semiconductors.

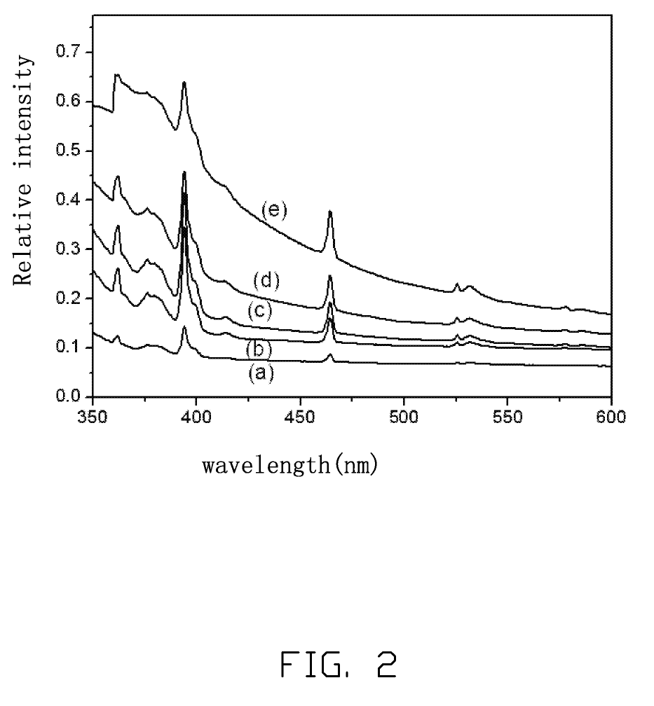

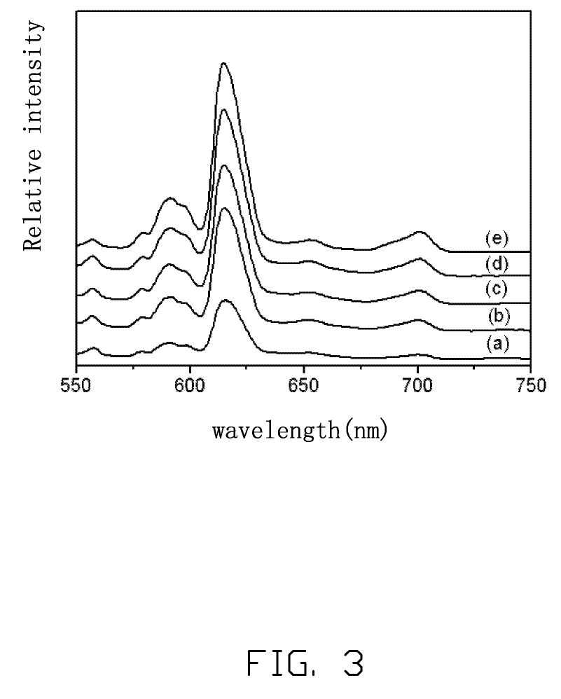

The glass layer 12 contains europium (Eu) or europium-containing compound therein. As shown in FIGS. 2 and 3, the glass layer 12 is capable of changing the received light of a first wavelength (e.g, 350-470 nm) into light of a second wavelength (e.g, 570-720 nm) greater than the first wavelength and transmitting the light of the second wavelength to the light incident surface 101. In the present embodiment, the glass layer 12 is comprised of a silicate glass/borate glass doped with Eu or europium-containing compound. The silicate glass/borate glass is comprised of silicon dioxide (SiO₂), boron oxide (B₂O₃), and oxides of alkali metals (e.g., sodium oxide (Na₂O)). A molar percentage of Eu to all compounds in the silicate glass/borate glass (e.g., the sum of SiO₂, B₂O₃, and oxides of alkali metals) is less than 5%. In other embodiments, the molar percentage is less than 2.5%. In this condition, the glass layer 12 can also serve as an anti-reflection film, in other words, the glass layer 12 has a lower reflection rate and is capable of improving the light utilizing efficiency.

Eu exists in the silicate glass in the form of europium oxide (Eu₂O₃), which is an electrovalent type covalent oxide. Electrovalent type means that Eu in Eu₂O₃ tends to loose its three outermost electrons and therefore has similar properties to Eu³⁺ ions. In other words, Eu also exists in the silicate glass in the form of Eu³⁺ ions.

Process and material for manufacturing the glass layer 12 is selected according to the composition of the silicate glass. For example, metal Eu, or Eu-containing compound (e.g., europium chloride, europium oxide, europium carbonate) is mixed with materials of the silicate glass (e.g., SiO₂, B₂O₃, and Na₂O) and then heated to above 1300° C. to melt the mixture. The heating process may range from approximately 5 minutes to approximately 10 hours, and then the mixture is cooled to the room temperature (i.e, 25° C.) thereby obtaining the glass layer 12. It is understood that the heating temperature and heating time may vary according to different materials and devices.

In one embodiment, the glass layer 12 has a composition represented by the molecular formula 59SiO₂-33B₂O₃-8Na₂O-xEu₂O₃, wherein x=0.5˜2.5. That is, a molar percentage of Eu₂O₃ to the sum of SiO₂, B₂O₃, and Na₂O is in the range from 0.5% to 2.5%, and a molar percentage of Eu to the sum of SiO₂, B₂O₃, and Na₂O is in the range from 1% to 5%. In a process of synthesizing the composition, the mixture of SiO₂, B₂O₃, Na₂O, and Eu₂O₃ is placed in a platinum crucible and then heated to increase the temperature of the mixture at a speed of 10° C. per minutes. After the temperature of the mixture reaches to a point in the range from approximately 1400° C. to approximately 1500° C., the temperature is maintained for approximately 30 minutes thereby obtaining a melted mixture. The melted mixture is poured into a mold and fast cooled to obtain the glass layer 12. An additional annealing process is performed to reduce inner stress in the glass layer 12.

To test performance of glass layer 12 containing different contents of Eu₂O₃, five glass layer samples (a)-(e), as listed in table 1, are prepared and then tested. Properties of glass layer samples (a)-(e) are listed in table 2, which shows that glass transition temperature and density of glass layer samples increases along with the molar percentage of Eu₂O₃ added therein.

TABLE 1
composition of the glass layer

Composition
(molar percentage)

| glass layer samples | SiO₂ | B₂O₃ | Na₂O | Eu₂O₃ |
|---|---|---|---|---|
| (a) | 56.05 | 35.79 | 8.16 | 0.27 |
| (b) | 56.18 | 35.61 | 8.21 | 0.85 |
| (c) | 56.84 | 35.00 | 8.16 | 1.00 |
| (d) | 57.02 | 34.87 | 8.11 | 1.11 |
| (e) | 56.68 | 35.12 | 8.2 | 2.47 |

TABLE 2
properties of the glass layer samples

| | Coefficient of | | |
|---|---|---|---|
| Glass layer | thermal expansion | Glass transition | Density |
| samples | (CTE, 10⁻⁷/° C.) | temperature (T_{g}, ° C.) | (g/cm³) |
| (a) | 50.4 | 479 | 2.24 |
| (b) | 50.2 | 491 | 2.30 |
| (c) | 50.0 | 493 | 2.35 |
| (d) | 50.2 | 499 | 2.40 |
| (e) | 50.2 | 503 | 2.45 |

FIG. 2 illustrates ultraviolet visible absorption spectrums of glass layer samples (a)-(e), in which absorption peaks appear at 577 nm, 531 nm, 525 nm, 465 nm, 413 nm, 393 nm, 376 nm, and 361 nm. FIG. 3 illustrates fluorescence spectrums at 465 nm excitation of glass layer samples (a)-(e), in which emission peaks appear at 579 nm, 591 nm, 615 nm, and 700 nm. Similar results are also observed using excitation of other wavelength (for example, 361 nm, 376 nm, 393 nm, 413 nm). These indicate that the glass layer samples is capable of changing the received light of a first wavelength (e.g, 350-470 nm) into light of a second wavelength (e.g., 570-720 nm) greater than the first wavelength, which can be utilized by the photoelectric layer 113. As such, the light utilizing efficiency of the solar cell is improved.

While certain embodiments have been described and exemplified above, various other embodiments from the foregoing disclosure will be apparent to those skilled in the art. The present invention is not limited to the particular embodiments described and exemplified but is capable of considerable variation and modification without departure from the scope of the appended claims.

What is claimed is:

1. A solar cell, comprising:
a photoelectric conversion module for receiving light and converting the light into electric energy, the photoelectric conversion module having a light incident surface; and
a glass layer containing europium therein formed on the light incident surface, the glass layer configured for changing the received light of a first wavelength into light of a second wavelength greater than the first wavelength and transmitting the light of the second wavelength to the light incident surface.

2. The solar cell of claim 1, wherein the glass layer is comprised of silicate glass doped with europium or europium-containing compound.

3. The solar cell of claim 1, wherein the glass layer is comprised of borate glass doped with europium or europium-containing compound.

4. The solar cell of claim 3, wherein the borate glass is doped with europium oxide, and a molar percentage of the europium oxide in the borate glass is equal to or less than 2.5%.

5. The solar cell of claim 3, wherein the borate glass is comprised of silicon dioxide, boron oxide, and an oxide of one or more alkali metals.

6. The solar cell of claim 1, wherein the first wavelength is in the range from 350 nm to 470 nm, and the second wavelength is in the range from 570 nm to 720 nm.

7. The solar cell of claim 1, wherein the solar cell comprises a front electrode, a back electrode, and a photoelectric layer sandwiched between the transparent conductive layer and the back electrode, the photoelectric layer comprising a light incident surface, the front electrode and the glass layer being both formed on the light incident surface.

8. The solar cell of claim 7, wherein the front electrode is comprised of a transparent conductive layer sandwiched between the light incident surface of the photoelectric layer and the glass layer.

9. The solar cell of claim 1, wherein the glass layer is represented by a molecular formula 59SiO₂-33B₂O₃-8Na₂O-xEu₂O₃, wherein x=0.5-2.5.

10. The solar cell of claim 1, wherein a molar percentage of Eu in the glass layer is less than 5%.

11. The solar cell of claim 1, wherein a molar percentage of Eu in the glass layer is less than 2.5%.

12. The solar cell of claim 1, wherein the glass layer contains europium oxide therein.

13. The solar cell of claim 1, wherein the glass layer contains Eu³⁺ therein.
